(19) United States
(12) Patent Application Publication
(10) Pub. No.: US 2004/0188684 A1
(43) Pub. Date: Sep. 30, 2004

(54) Selective deposition of smooth silicon, germanium, and silicon-germanium alloy epitaxial films

(76) Inventors: Glenn A. Glass, Beaverton, OR (US); Anand Murthy, Portland, OR (US)

Correspondence Address: Jan Carol Little, BLAKELY, SOKOLOFF, TAYLOR & ZAFMAN LLP, Seventh Floor, 12400 Wilshire Boulevard, Los Angeles, CA, 90025-1026, US

(21) Appl. No.: 10/405,053

(22) Filed: Mar. 31, 2003

(51) Int. Cl. H01L 29/04; H01L 31/112; H01L 21/302

(52) U.S. Cl. 257/65; 257/66; 257/616; 438/166; 438/752; 438/933

(57) ABSTRACT

Chemical vapor deposition (CVD) is commonly used to blanket deposit or selectively deposit and grow an epitaxial film on a substrate. When the exposed portion of a substrate's crystalline material is relatively small, however, conventional CVD techniques do not work well and the resulting films are rough and may be unusable. Embodiments of the present invention provide a CVD process for selectively depositing smooth silicon, germanium, or silicon germanium alloy epitaxial films on a substrate's exposed crystalline material when the amount of exposed crystalline material is less than approximately twenty percent.

### BACKGROUND

1. Field

Embodiments of the present invention relate to semiconductor transistors and, in particular, to semiconductor transistors with epitaxial films.

2. Discussion of Related Art

In general, the basic process used in fabricating integrated circuits includes a material deposition stage, a patterning stage, a material removal stage, a doping stage, and a heating stage. The particular stages used depend on the type of devices to be included on the integrated circuit. For example, when the integrated circuit is silicon based with millions of transistors interconnected, the process takes into consideration that features of the transistor, such as the source, drain, and gate, must be formed and that the semiconductor substrate material is silicon.

Chemical vapor deposition (CVD) is a mature semiconductor process technology used to deposit thin films on semiconductor devices. CVD technique can be classified as either “blanket deposition” in which the material to be deposited is mixed with a carrier gas and deposited all over the substrate or “selective deposition” in which the material to be deposited is mixed with a carrier gas and deposited selectively only in particular spaces on the substrate.

CVD is commonly used to deposit and grow an epitaxial film on a substrate. Epitaxial growth occurs when the crystallographic structure of the substrate is reproduced in the growing material. Any crystallographic defects in the substrate also are reproduced in the growing material. The result should be a single smooth crystalline structure.

It is also common to coat a substrate with a dielectric material and etch out portions of the dielectric material to expose selective portions of the substrate crystalline material. The exposed portion of a substrate's crystalline material is usually a very high percentage of the substrate's total surface area. In these instances, selective deposition of epitaxial films can be accomplished using conventional CVD techniques. There is a single smooth crystalline structure.

However, when the exposed portion of a substrate's crystalline material is relatively small, conventional CVD does not work well. The epitaxial film has no single smooth crystalline structure. The surface morphology is rough and there is a high concentration of (111) stacking faults. These crystalline imperfections degrade the electronic properties of the film. The resistance of the film is increased and there may be shorting to the substrate caused by the pits in the film surface.

In some instances, a transition from epitaxial growth to polycrystalline growth takes place and the crystallographic structure of the substrate is not exactly reproduced in the film. Instead, the atoms in the film are oriented in a random manner and the resulting device may be unusable especially when the epitaxial films may be used to produce semiconductor layers with additives such as n- and p-type dopants.

### BRIEF DESCRIPTION OF THE DRAWINGS

In the drawings, like reference numbers generally indicate identical, functionally similar, and/or structurally equivalent elements. The drawing in which an element first appears is indicated by the leftmost digit(s) in the reference number, in which:

FIG. 1 is a flowchart illustrating a process for fabricating a semiconductor transistor according to an embodiment of the present invention;

FIG. 2 is a cross-section view of a semiconductor transistor according to an embodiment of the present invention;

FIG. 3 is a cross-section view of a semiconductor transistor according to an alternative embodiment of the present invention; and

FIG. 4 is a high-level block diagram of a system according to an embodiment of the present invention.

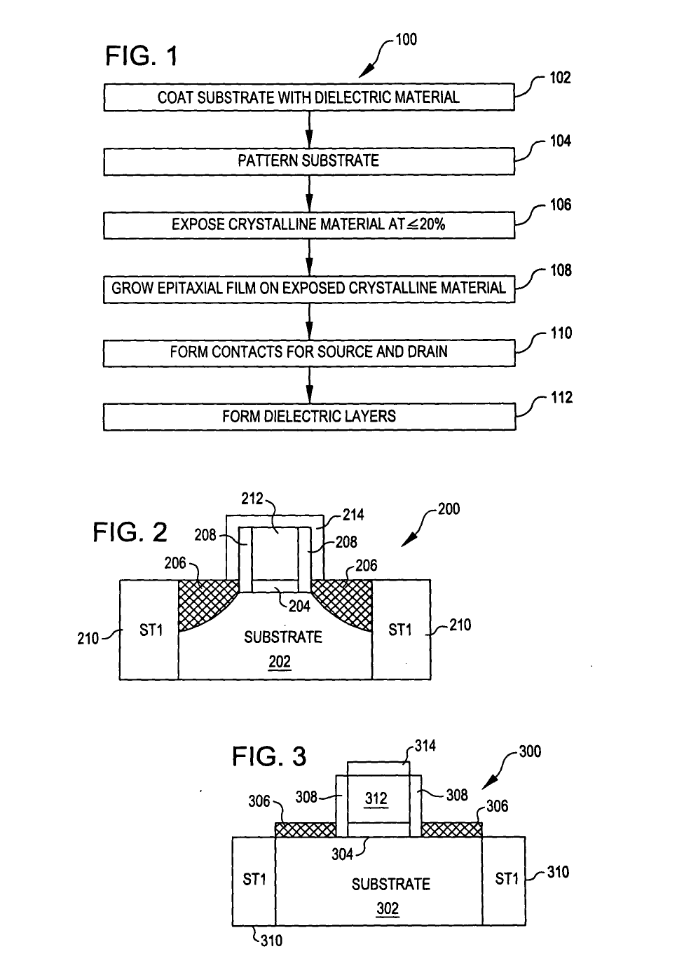

### DETAILED DESCRIPTION OF THE ILLUSTRATED EMBODIMENTS

Embodiments of the present invention are directed to a process regime that permits a high degree of surface smoothness for epitaxial films deposited on substrates having less than twenty percent of their crystalline structure exposed. FIG. I is a flowchart illustrating a process 100 for fabricating one or more semiconductor transistors according to an embodiment of the present invention. A machine-readable medium with machine-readable instructions thereon may be used to cause a processor to perform the process 100. Of course, the process 100 is only an example process and other processes may be used.

In a block 102, the substrate is coated with amorphous dielectric material silicon oxide (SiO₂), silicon nitride (SiN), or other suitable dielectric.

In a block 104, the coated substrate is patterned using known photolithographic techniques, for example. In one embodiment, the patterns may be for the formation of one or more wells, sources, drains, and or gates for the semiconductor transistor.

In a block 106, the patterned portions of the coated substrate are removed to expose crystalline material of the substrate using known reactive ion etching techniques, for example. In one embodiment, approximately twenty percent of crystalline material is exposed. In an alternative embodiment, less than twenty percent of crystalline material is exposed. In still another embodiment, approximately ten to fifteen percent of crystalline material is exposed. The etched portions may be smoothed using known after-etching techniques.

The crystalline material may be silicon crystalline material. Alternatively, the crystalline material may be germanium crystalline material.

In a block 108, an epitaxial film is grown on the exposed crystalline material. In one embodiment, the exposed crystalline material forms a recess (or well) in the substrate. In this embodiment, the epitaxial film grows in the recess of the exposed crystalline material and fills in the recess up to the surface of the substrate. In an alternative embodiment, only the surface of the substrate is removed to expose the crystalline material. In this embodiment, the epitaxial film grows on top of and above the surface of the exposed crystalline material.

The epitaxial film may be grown in a chemical vapor deposition (CVD) reactor using rapid thermal chemical vapor deposition (RTCVD) or reduced pressure chemical vapor deposition (RPCVD). The carrier gas may be a combination of gaseous phases of hydrogen (H₂) and hydrochloric acid (HCl). If the material to be deposited is silicon, the silicon source may be disilane (Si₂H₆) commonly used for rapid low temperature deposition of epitaxial silicon, amorphous silicon, and silicon based dielectrics. Alternatively, the silicon source may be dichlorosilane (DCS) or silane (SiH₄) gas. If the material to be deposited is germanium, the germanium source may be germane gas. If the material to be deposited is silicon-germanium, the silicon-germanium may be a combination of dichlorisilane (DCS), silane, di-silane, and/or germane gases.

The CVD process implemented according to embodiments of the present invention leaves a layer of silicon, germanium, or silicon-germanium alloy on the exposed areas of the substrate. For example, a layer of silicon or silicon-germanium may remain on the exposed crystalline material of a silicon substrate. Alternatively, a layer of germanium or silicon-germanium may remain on the exposed crystalline material of a germanium substrate.

In one embodiment of the present invention, the flow rate of hydrogen (H₂) may be significantly less than the flow rate of hydrogen (H₂) in known CVD processes. The flow rate of hydrogen (H₂) is not normally recognized as affecting selective epitaxial deposition of silicon, germanium, or silicon-germanium using known CVD processes. This is because selective epitaxial deposition (e.g., when the portion of the exposed crystalline material is less than approximately twenty percent) of silicon, germanium, or silicon-germanium is a fairly new technology while CVD is a fairly mature technology. As it turns out, the carrier gas flows used to grow epitaxial films using standard blanket deposition techniques do not work for selective epitaxial deposition (e.g., when the portion of the exposed crystalline material is less than approximately twenty percent) of silicon, germanium, or silicon-germanium.

The lowered hydrogen (H₂) flow rate permits a high degree of surface smoothness for selectively deposited epitaxial films. As the hydrogen (H₂) flow rate is lowered even further, to approximately 0.25 of conventional CVD blanket deposition hydrogen (H₂) flow rates, the surface smoothness of selectively doped epitaxial films increases.

In a block 110, contacts are formed for the source and the drain. In one embodiment, an oxide layer is deposited on the substrate using known deposition techniques, windows are opened in the oxide layer for the contacts using known CVD techniques, and contacts are metalized using known techniques.

In a block 112, a gate dielectric layer may be grown on the substrate, shallow trench isolation (STI) regions may be formed around the substrate to separate wells in one portion of the substrate from wells in another portion of the substrate, and vertical sidewall spacers may be formed on the sides of the gate dielectric layer using known CVD blanket deposition, sputter deposition, evaporation, oxide growth, or other suitable technique. The STI regions, spacers, and gate dielectric layer form part of the semiconductor transistor. The transistor may be annealed. Other known salicide processes may also be used.

FIG. 2 is a cross-section view of a transistor 200 according to an embodiment of the present invention. The transistor 200 may be part of a complementary metal oxide semiconductor (CMOS) device. Alternatively, the transistor 200 may be part of a bipolar complementary metal oxide semiconductor (BICMOS) device. Alternatively still, the transistor 200 may be part of a flash memory.

The example transistor 200 includes a substrate 202, a gate dielectric layer 204 formed on the substrate 202, two wells 206, two vertical sidewall dielectric spacers 208 formed on the sides of the gate dielectric layer 204, and shallow trench isolation (STI) regions 210 formed around the wells 206.

A gate region 212 may be formed on the gate dielectric layer 204. Dielectric material 214 may be formed around the gate region 212 and the vertical sidewall spacers 208.

The gate dielectric layer 204 may be any suitable insulator to insulate the gate region 212 from the substrate 202. The two vertical sidewall dielectric spacers 208 may be dielectric material suitable for preventing material in the wells 206 from contacting the gate region 212 or the gate dielectric layer 204 on the sides. The STI regions 210 may be dielectric material and separate the transistor wells 206 from other wells 206 formed on the transistor 200.

In one embodiment of the present invention, the wells 206 may be formed by creating a recess in the substrate 202 to expose crystalline material. The wells 206 may be approximately twenty percent or less of the partially fabricated transistor 200.

An epitaxial film (as represented by cross hatches) has been grown on the exposed crystalline material in the wells 206 according to embodiments of the present invention. The lowered hydrogen (H₂) flow rate used to selectively deposit the epitaxial film permits improved selectivity to silicon oxide (SiO) and/or silicon nitride (SiN). For example, there is little or no epitaxial film growth on the silicon oxide (SiO) and/or silicon nitride (SiN). The vast majority of the film remains on the exposed crystalline material.

In embodiments of the present invention, the exposed crystalline material may be germanium crystalline material or silicon crystalline material. In alternative embodiments, the epitaxial film may be a silicon epitaxial film, a germanium epitaxial film, or a silicon-germanium epitaxial film.

FIG. 3 is a cross-section view of a transistor 300 according to an embodiment of the present invention. The transistor 300 may be part of a complementary metal oxide semiconductor (CMOS) device. Alternatively, the transistor 300 may be part of a bipolar complementary metal oxide semiconductor (BICMOS) device. Alternatively still, the transistor 300 may be part of a flash memory.

The example transistor 300 includes a substrate 302, a gate dielectric layer 304 formed on the substrate 302, two epitaxial films 306 grown on exposed crystalline material of the substrate 302 according to embodiments of the present invention, two vertical sidewall dielectric spacers 308 formed on the sides of the gate dielectric layer 304, and shallow trench isolation (STI) regions 310 formed around the substrate 302.

A gate region 312 may be formed on the gate dielectric region 304. Dielectric material 314 may be formed on top of the gate region 312.

In one embodiment of the present invention, the exposing crystalline material in the substrate 302 may be approximately twenty percent or less of the transistor 300. The lowered hydrogen (H₂) flow rate used to selectively deposit the epitaxial film permits improved selectivity to silicon oxide (SiO) and/or silicon nitride (SiN). For example, there is little or no epitaxial film growth on the silicon oxide (SiO) and/or silicon nitride (SiN). The vast majority of the film remains on the exposed crystalline material.

The remaining portions of the transistor 300 may be amorphous dielectric material. The exposed crystalline material may be germanium crystalline material or silicon crystalline material. In alternative embodiments, the epitaxial film may be a silicon epitaxial film, a germanium epitaxial film, or a silicon-germanium epitaxial film.

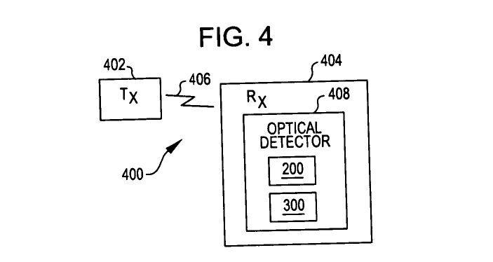

FIG. 4 is a high-level block diagram of a system 400 according to an embodiment of the present invention. The example system 400 includes an optical transmitter 402, an optical receiver 404, and an optical signal 406. The optical signal 406 may be transmitted from the optical transmitter 402 to the optical receiver 404 via optical fiber, free space, or other suitable medium.

The example optical receiver 404 includes an optical detector 408, which detects the optical signal 406 and converts the optical signal 406 to an electrical signal.

The example optical detector 408 includes the transistor 200, the transistor 300, and/or any transistor fabricated according to embodiments of the present invention. In one embodiment, the optical detector 408 may be a germanium photodetector.

Embodiments of the invention can be implemented using hardware, software, or a combination of hardware and software. In implementations using software, the software may be stored on a computer program product (such as an optical disk, a magnetic disk, a floppy disk, etc.) or a program storage device (such as an optical disk drive, a magnetic disk drive, a floppy disk drive, etc.).

The above description of illustrated embodiments of the invention is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize. These modifications can be made to the invention in light of the above detailed description.

In the above description, numerous specific details, such as particular processes, materials, devices, and so forth, are presented to provide a thorough understanding of embodiments of the invention. One skilled in the relevant art will recognize, however, that the embodiments of the present invention can be practiced without one or more of the specific details, or with other methods, components, etc. In other instances, well-known structures or operations are not shown or described in detail to avoid obscuring the understanding of this description.

Some parts of this description have been presented using terms such as, silicon, germanium, deposition, substrate, and so forth. These terms are commonly employed by those skilled in the art to convey the substance of their work to others skilled in the art.

Various operations have been described as multiple discrete blocks performed in turn in a manner that is most helpful in understanding the invention. However, the order in which they are described should not be construed to imply that these operations are necessarily order dependent or that the operations be performed in the order in which the blocks are presented.

Reference throughout this specification to “one embodiment” or “an embodiment” means that a particular feature, structure, process, block, or characteristic described in connection with an embodiment is included in at least one embodiment of the present invention. Thus, the appearance of the phrases “in one embodiment” or “in an embodiment” in various places throughout this specification does not necessarily mean that the phrases all refer to the same embodiment. The particular features, structures, or characteristics may be combined in any suitable manner in one or more embodiments.

The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

What is claimed is:

1. A method of making a semiconductor transistor, comprising:
selectively growing a single crystal epitaxial film on less than or equal to approximately twenty percent of exposed crystalline material of a substrate.

2. The method of claim 1, wherein selectively growing the single crystal epitaxial film on less than or equal to approximately twenty percent of exposed crystalline material of the substrate comprises depositing an epitaxial film using chemical vapor deposition (CVD).

3. The method of claim 2, wherein depositing the epitaxial film using CVD comprises applying a silicon source, hydrogen, and hydrochloric acid to the exposed crystalline material.

4. The method of claim 2, wherein depositing the epitaxial film using CVD comprises applying a germanium source, hydrogen, and hydrochloric acid to the exposed crystalline material.

5. The method of claim 2, wherein depositing the epitaxial film using CVD comprises applying a silicon-germanium source, a hydrogen carrier, and hydrochloric acid to the exposed crystalline material.

6. The method of claim 2, wherein selectively growing the single crystal epitaxial film on less than or equal to approximately twenty percent of exposed crystalline material of the substrate comprises selectively growing the single crystal epitaxial film on less than or equal to approximately twenty percent of exposed silicon crystalline material.

7. The method of claim 4, wherein selectively growing the single crystal epitaxial film on less than or equal to approximately twenty percent of exposed crystalline material of the substrate comprises selectively growing the single crystal epitaxial film on less than or equal to approximately twenty percent of exposed silicon crystalline material.

8. The method of claim 5, wherein selectively growing the single crystal epitaxial film on less than or equal to approximately twenty percent of exposed crystalline material of the substrate comprises selectively growing the single crystal epitaxial film on less than or equal to approximately twenty percent of exposed silicon-germanium alloy crystalline material.

9. The method of claim 1, wherein selectively growing the single crystal epitaxial film on less than or equal to approximately twenty percent of exposed crystalline material of the substrate comprises growing an epitaxial film on a substrate surface.

10. The method of claim 10, wherein growing an epitaxial film on the exposed crystalline material comprises growing an epitaxial film in a substrate recess.

11. The method of claim 1, further comprising selectively growing the single crystal epitaxial film on less than or equal to approximately ten percent of exposed crystalline material of the substrate comprises.

12. The method of claim 2, wherein depositing the epitaxial film using CVD comprises depositing the epitaxial film using rapid thermal chemical vapor deposition (RTCVD).

13. A semiconductor transistor, comprising:
a substrate having less than or equal to approximately twenty percent exposed crystalline material;
an epitaxial film grown on the exposed crystalline material.

14. The semiconductor transistor of claim 13, wherein the epitaxial film is grown in a recess of the substrate.

15. The semiconductor transistor of claim 13, wherein the epitaxial film is grown on a surface of the substrate.

16. The semiconductor transistor of claim 13, wherein the exposed crystalline material is silicon crystalline material.

17. The semiconductor transistor of claim 13, wherein the exposed crystalline material is germanium crystalline material.

18. The semiconductor transistor of claim 16, wherein the epitaxial film is silicon-germanium.

19. The semiconductor transistor of claim 17, wherein the epitaxial film is silicon-germanium.

20. The semiconductor transistor of claim 16, wherein the epitaxial film is silicon.

21. The semiconductor transistor of claim 17, wherein the epitaxial film is germanium.

22. The semiconductor transistor of claim 13, wherein the substrate includes less than or equal to approximately ten percent exposed crystalline material.

23. A system, comprising:
a transmitter to transmit an optical signal;
an optical detector coupled to detect the optical signal, the optical detector comprising a semiconductor transistor, the semiconductor transistor having a substrate with less than or equal to approximately twenty percent exposed crystalline material and an epitaxial film grown on the exposed crystalline material.

24. The system of claim 22, wherein the substrate includes less than or equal to approximately ten percent exposed crystalline material.

25. The system of claim 24, wherein the crystalline material is silicon crystalline material or germanium crystalline material.

26. The system of claim 24, wherein the epitaxial film is one of silicon, germanium, or silicon-germanium.
